(19) United States
(12) Patent Application Publication
(10) Pub. No.: US 2014/0261685 A1
(43) Pub. Date: Sep. 18, 2014

(54) THIN FILM PHOTOVOLTAIC DEVICE WTIH LARGE GRAIN STRUCTURE AND METHODS OF FORMATION

(71) Applicant: FIRST SOLAR, INC., Perrysburg, OH (US)

(72) Inventors: Feng Liao, Perrysburg, OH (US); Jigish Trivedi, Perrysburg, OH (US); Zhibo Zhao, Novi, MI (US); Rick C. Powell, Ann Arbor, MI (US); Long Cheng, Perrysburg, OH (US); Markus Gloeckler, Perrysburg, OH (US); Benyamin Buller, Sylvania, OH (US); Igor Sankin, Perrysburg, OH (US); Jeremy Brewer, Swanton, OH (US)

(73) Assignee: FIRST SOLAR, INC., Perrysburg, OH (US)

(21) Appl. No.: 14/209,094

(22) Filed: Mar. 13, 2014

Related U.S. Application Data
(60) Provisional application No. 61/789,536, filed on Mar. 15, 2013.

(51) Int. Cl. H01L 31/0352; H01L 31/0203; H01L 31/0296

(52) U.S. Cl. CPC H01L 31/035272; H01L 31/0296; H01L 31/0203
USPC 136/260; 136/252; 438/64

(57) ABSTRACT

Embodiments include photovoltaic devices that include at least one absorber layer, e.g. CdTe and/or CdSₓTe₁₋ₓ (where 0≦x≦1), having an average grain size to thickness ratio from greater than 2 to about 50 and an average grain size of between about 4 μm and about 14 μm and methods for forming the same.

### CLAIM OF PRIORITY

This application claims priority under 35 U.S.C. §119(e) to U.S. Provisional Patent Application Ser. No. 61/789,536 filed on Mar. 15, 2013, which is hereby incorporated by reference in its entirety.

### TECHNICAL FIELD

Disclosed embodiments relate generally to photovoltaic devices, which include photovoltaic cells and photovoltaic modules containing a plurality of photovoltaic cells, and more particularly to photovoltaic devices that include an absorber layer having large sized grains and methods of forming such photovoltaic devices.

### BACKGROUND

Thin-film photovoltaic devices can include semiconductor material deposited over a substrate such as glass, for example, with a first layer of the semiconductor material serving as an n-type window layer and a second layer of the semiconductor material serving as a p-type absorber layer. The semiconductor window layer forms a p/n junction with the semiconductor absorber layer where incident light is converted to electricity. During operation, photons pass through the photovoltaic device and are converted to electrons and holes in the absorber layer. A built-in electric field at the p/n junction promotes the movement of these photo-generated electrons and holes, which produces electric current to be output by the photovoltaic device.

One factor that limits thin-film photo-conversion efficiency is reduced carrier lifetime, that is, the reduced lifetime of the photo-generated electrons. Carrier lifetime is defined as the average time it takes electrons to lose their excited energy by recombining with a hole. Recombination may occur near structural defects such as grain boundaries. For example, absorber layers are often made of materials that are made up of crystallites. Crystallites are small, often microscopic crystals (also known as “grains”) held together through highly defective boundaries (i.e., interfaces where crystals of different orientations meet). These defective boundaries have the ability to trap the photo-generated electrons long enough for holes to come by and recombine with them.

To increase carrier lifetime, recombination of the photo-generated electrons with holes must be reduced. Increased carrier lifetime increases open-circuit voltage (Voc—a measure of PV device efficiency indicating the maximum voltage the device can produce) as fewer excited electrons and holes will be lost to recombination. To reduce recombination, it is desirable to increase absorber layer grain size, i.e., the average size of crystallites within the absorber layer and/or repair or passivate the defective boundaries. For an absorber layer of a specific thickness, larger grain size results in a larger grain size to thickness ratio (d/t). The larger the absorber layer grain size to thickness ratio average (which results in a reduced area of grain boundaries), the more difficult it is for excited electrons to lose their excited energy by recombination, which extends carrier lifetime.

The n-type window and p-type absorber layers can be formed of different Group 12 to Group 16 semiconductor materials, with one particular example being a window layer formed of cadmium sulfide (CdS) and an absorber layer formed of cadmium telluride (CdTe). During photovoltaic device processing, to increase carrier lifetime, a CdTe semiconductor absorber layer may be subjected to a chloride treatment. Generally, chloride treatments include a step in which chloride, in the form of a cadmium chloride (CdCl2) solution for example, is applied to an absorber layer followed by a heat anneal step in which the absorber layer is subjected to a temperature of 400°-440° C., for about 30 minutes, with a 15-minute-soaking time at a peak temperature. The heat anneal step increases the size of the CdTe crystallites by fostering recrystallization (a step in which two or more crystals or grains are combined together to form a bigger crystal or grain). The application of the chloride repairs or passivates the boundary defects in the CdTe by incorporation of chlorine atoms (or ions) from the cadmium chloride.

Generally, the average grain size to thickness ratio (d/t) of a CdTe absorber layer that has been subjected to a conventional chloride treatment is from about 0.5 to about 2. It would, however, be desirable to have photovoltaic devices that include CdTe absorber layers with an average grain size to thickness ratio that is larger than 2 to further increase carrier lifetime and thereby improve open-circuit voltage.

### BRIEF DESCRIPTION OF THE DRAWINGS

FIGS. 1-4A are cross-sectional views of photovoltaic devices according to embodiments.

FIG. 5 is a cross-sectional view of the photovoltaic device of FIG. 2 at an intermediate stage of processing, according to an embodiment.

FIG. 5A is a cross-sectional view of the photovoltaic device of FIG. 2A at an intermediate stage of processing, according to an embodiment.

FIG. 6 is a cross-sectional view of the photovoltaic device of FIG. 3 at an intermediate stage of processing, according to an embodiment.

FIG. 6A is a cross-sectional view of the photovoltaic device of FIG. 3A at an intermediate stage of processing, according to an embodiment.

FIG. 7 is a cross-sectional view of the photovoltaic device of FIG. 4 at an intermediate stage of processing, according to an embodiment.

FIG. 7A is a cross-sectional view of the photovoltaic device of FIG. 4A at an intermediate stage of processing, according to an embodiment.

FIG. 8 is a schematic of a zone of an oven used for halide compound treatment of a semiconductor layer, according to an embodiment.

FIG. 9 is a cross-sectional view of the photovoltaic device of FIGS. 2-4A at a stage of processing subsequent to that of FIGS. 5-7A, according to an embodiment.

FIG. 10 is a schematic of a zone of an oven used to deposit a containment layer, according to an embodiment.

FIGS. 11-12 are cross-sectional views of the photovoltaic device of FIGS. 2-4A at a stage of processing subsequent to that of FIGS. 5-7A, according to an embodiment.

FIGS. 13A-14 are schematics of a zone of an oven used to anneal a semiconductor layer, according to embodiments.

FIG. 15 is a schematic of a zone of an oven used to remove a containment layer or cover, according to an embodiment.

### DETAILED DESCRIPTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical, or procedural changes may be made to the specific embodiments disclosed without departing from the spirit and scope of the invention.

Embodiments described herein provide photovoltaic devices having a telluride containing semiconductor absorber layer, such as CdTe or CdSₓTe₁₋ₓ (0<x<1 with large sized grains (e.g., anywhere from about 4 μm to about 14 μm, from about 5 μm to about 8 μm, or from about 8 μm to about 14 μm) and/or an average grain size to thickness ratio greater than 2, for example, about 10 to about 40, about 4 to about 20, or about 2.5 to about 10. With an average grain size to thickness ratio that is larger than the conventional 0.5 to 2, the number of grain boundaries within the semiconductor absorber layer is decreased. Applicants have observed that photovoltaic devices having an absorber layer with larger average grain sizes, and more specifically, an average grain size to thickness ratio greater than 2 can have carrier lifetimes that are increased by up to two orders of magnitude compared to photovoltaic devices having absorber layers with smaller average grain size to thickness ratios.

FIG. 1 illustrates one example of a photovoltaic device 100 according to one embodiment. The photovoltaic device 100 includes a semiconductor layer stack 111, the various embodiments of which are discussed in greater detail below in connection with FIGS. 2-4A. Photovoltaic device 100 includes a substrate 101 with a transparent conductive oxide (TCO) stack 110, semiconductor layer stack 111 and back contact 108 deposited thereon. A back support 109 may be formed over the back contact 108. Substrate 101 and back support 109 may be of a transparent material such as glass (e.g., soda lime glass, borosilicate glass, low Fe glass or float glass). The substrate 101 needs to be made of a transparent material for light to penetrate therethrough. Unlike the substrate 101, however, the back support 109 need not be transparent, it may alternatively be made of a carbon fiber or polycarbonate material. Back support 109, in combination with substrate 101 and an edge seal (not shown but applied to the sides of the device 10), protect the plurality of layers of the device 100 from moisture intrusion, physical damage, environmental hazards and electrical shock to those who handle device 10.

The TCO stack 110 may include a barrier layer 102, a TCO layer 103 and a buffer layer 104. The barrier layer 102 is positioned between the substrate 101 and the TCO layer 103 to lessen diffusion of sodium or other contaminants from the substrate 101 to other layers of the photovoltaic device 10, including the semiconductor layer stack 111. The TCO layer 103 is deposited on the barrier layer 102 and is used as one of two electrodes through which generated electricity is made available externally. The buffer layer 104 is deposited upon the TCO layer 103 and is used to provide a smooth surface for the formation of the semiconductor layer stack 111.

The barrier layer 102 may include, for example, silicon dioxide, silicon aluminum oxide, tin oxide, silicon nitride, or other suitable material or a combination thereof. The barrier layer 102 may have a thickness ranging from about 250 Å to about 750 Å.

The TCO layer 103 may include, for example, cadmium stannate, cadmium tin oxide, fluorine doped tin oxide, cadmium indium oxide, aluminum-doped zinc oxide, or other transparent conductive oxide or a combination thereof. The TCO layer 103 may have a thickness ranging from about 500 Å to about 5000 Å.

The buffer layer 104 may include, for example, tin oxide (e.g., tin dioxide), zinc tin oxide, zinc oxide, zinc magnesium oxide, or other suitable material or a combination thereof. The buffer layer 104 may have a thickness ranging from about 50 Å to about 2000 Å.

Semiconductor layer stack 111 can be deposited over buffer layer 104, if present, and includes at least one n-type semiconductor window layer and one p-type semiconductor absorber layer to form a p/n junction. As noted above, conversion of solar energy to electricity occurs at or near the p/n junction. The semiconductor stack 111 is described in more detail in connection with FIGS. 2-4A below.

Back contact 108 is formed over the semiconductor layer stack 111 and serves as the second of the two electrodes through which the generated electricity is provided externally. Suitable materials for the back contact 108 include, for example, copper, aluminum, silver, gold or other metals or a combination thereof.

Optionally, additional materials, layers and/or films may be included in or on the outside of device 10, such as anti-reflective (AR) coatings, color suppression layers, among others. As one example, the device 100 can include a zinc telluride (ZnTe) layer 113, illustrated as optional by the dotted line in FIG. 1, between back contact metal 108 and semiconductor layer stack 111. The presence of the ZnTe layer 113 has been experimentally shown to improve device efficiency by reducing electron/hole recombination which might otherwise occur at the interface between the semiconductor stack 111 and back contact 108. The zinc telluride layer, if employed, can have a thickness of about 10 nm to about 500 nm.

The above-discussed layers of the photovoltaic device 10, as shown in FIG. 1, can be formed in the order indicated above the substrate 101 by any suitable known deposition technique such as, for example, physical vapor deposition, atomic layer deposition, chemical vapor deposition, electrodeposition, screen printing, sputtering (e.g., DC pulsed sputtering, RF sputtering, or AC sputtering), chemical bath deposition, closed space sublimation, or vapor transport deposition. Alternatively, the layers shown in FIG. 1 can be formed in the reverse order, beginning with the back support 109, using deposition techniques similar to those described, as desired. Each layer in photovoltaic device 100 may in turn include more than one layer or film. Additionally, each layer can cover all or a portion of the photovoltaic device 100 and/or all or a portion of the layer or substrate underlying the layer. For example, a “layer” can include any amount of any material that contacts all or a portion of a surface.

FIGS. 2-4A illustrate the photovoltaic device 100 and depict the semiconductor layer stack 111 according to alternative embodiments.

In FIG. 2, the semiconductor layer stack 111 includes a semiconductor absorber layer 106 made of CdTe. The semiconductor absorber layer 106 can have a thickness ranging from about 1 μm to about 10 μm, for example, from about 9 μm to about 10 μm, or about 3 μm. The CdTe absorber layer 106 has large sized grains 118. The absorber layer 106 may have an average grain size of about 4 μm to about 14 μm, of about 8 μm to about 14 μm, or of about 5 μm to about 8 μm. It is noted that these average grain sizes are larger than the average grain size in the originally deposited absorber layer due to recrystallization during a chloride heat treatment, described further below. The absorber layer 106 has a ratio of average grain size to thickness (d/t) from greater than 2 to about 50, from about 4 to about 20, or from about 2.5 to about 10.

In the FIG. 2 embodiment, there is no separate window layer 122 (see FIG. 2A). Instead, to reduce size and processing steps, the p/n junction is formed between the p-type semiconductor absorber layer 106 and the buffer layer 104, which, in the FIG. 2 embodiment is an n-type material, such as SnO₂ or fluorine doped SnO₂ and acts as a window layer.

The FIG. 2A embodiment is the same as that of FIG. 2, except that it includes an optional n-type semiconductor window layer 122 may be included in the semiconductor layer stack 111 between buffer layer 104 and absorber layer 106. The window layer 122 can be formed of CdS or CdZnS, as examples. In this arrangement, the p/n junction is at the interface of the optional window layer 122 and the absorber layer 106. The optional window layer 122 can have a thickness ranging from about 0.01 μm to about 0.1 μm. The absorber layer 106 of FIG. 2A has an average grain size and a ratio of average grain size to thickness (d/t) that is substantially the same as that of the absorber layer 106 shown in FIG. 2.

The semiconductor absorber layer 106 and optional window layer 122 can be formed by any suitable known deposition technique described above such as by close-space sublimation or vapor transport deposition. Once formed, the semiconductor absorber layer 106 is processed in the manner described in detail below to achieve the desired average grain size and ratio of average grain size to thickness.

FIG. 3 depicts the semiconductor layer stack 111 according to another embodiment. Instead of a CdTe absorber layer 106 as in the FIGS. 2 and 2A embodiments, the FIG. 3 embodiment includes a semiconductor absorber layer 107 made of CdSₓTe₁₋ₓ where 0≦x≦1, and more preferably 0.001≦x≦0.03. The CdSₓTe₁₋ₓ, absorber layer 107 can have a thickness ranging from about 1 μm to about 10 μm, for example, from about 9 μm to about 10 μm, or about 3 μm. The CdSₓTe₁₋ₓ absorber layer 107 is multi-crystalline (i.e., there are a plurality of larger-size grains 118′). The CdSₓTe₁₋ₓ absorber layer 107 has an average grain size from about 4 μm to about 14 μm, from about 8 μm to about 14 μm, or from about 5 μm to about 8 μm. It is again noted that the average grain size may be larger than the deposited absorber layer thickness, due to recrystallization during heat annealing, described further below. The CdSₓTe₁₋ₓ absorber layer 107 has a ratio of average grain size to thickness (d/t) from about 2 to about 50, from about 4 to about 20, or from about 2.5 to 10.

The CdSₓTe₁₋ₓ absorber layer 107 can be formed to have an average sulfur concentration from about 1×10¹⁷ atoms/cm³ to about 1×10²⁰ atoms/cm³, or from about 1×10¹⁷ atoms/cm³ to about 1×10¹⁹ atoms/cm³. The concentration of sulfur may be uniform within the grains 118′. However, sulfur may be present in higher concentrations at grain boundaries 117′ and the interface of the TCO stack 110 and the CdSₓTe₁₋ₓ absorber layer 107 than within the grains 118′. Alternatively, the concentration of sulfur can be higher adjacent to the TCO stack 110, within the grains 118′ and/or at the grain boundaries 117′, and decrease as the distance from the TCO stack 110 increases.

In the FIG. 3 embodiment, there is no separate window layer 122 (see FIG. 2A). Instead, to reduce size and processing steps, the p/n junction is formed between the p-type semiconductor absorber layer 107 and the buffer layer 104, which, in the FIG. 3 embodiment is an n-type material, such as SnO₂ or fluorine doped SnO₂ and acts as a window layer.

The FIG. 3A embodiment is the same as that of FIG. 2, except that it includes an optional n-type semiconductor window layer 122 may be included in the semiconductor layer stack 111 between the buffer layer 104 and semiconductor absorber layer 107. This window layer may be formed of CdS or CdZnS, as examples. The optional window layer 122 can have a thickness ranging from about 0.01 μm to about 0.1 μm. The p/n junction is formed between the optional window layer 122 and the absorber layer 107. The absorber layer 107 of FIG. 3A has an average grain size and a ratio of average grain size to thickness (d/t) that is substantially the same as that of the absorber layer 107 shown in FIG. 3.

FIG. 4 depicts the semiconductor layer stack 111 according to another embodiment. Instead of a CdTe absorber layer 106 as in the FIGS. 2 and 2A embodiments or the CdSxTe1-x (where 0≦x≦1) as in the FIGS. 3 and 3A embodiments, the FIG. 4 embodiment includes a semiconductor absorber layer 107 made of CdSₓTe₁₋ₓ, where 0≦x≦1, and more preferably 0.001≦x≦0.03, and a semiconductor absorber layer 106 made of CdTe. Both layers 106 and 107 in FIG. 4 collectively function as an absorber layer. The p/n junction is formed between the semiconductor absorber layer 107 and the buffer layer 104 which, in the FIG. 4 embodiment is an n-type material, such as SnO₂ or fluorine doped SnO₂ and acts as a window layer.

The FIG. 4A embodiment is the same as that of FIG. 4, except that it includes an optional n-type semiconductor window layer 122 may be included between the buffer layer 104 and semiconductor absorber layer 107. This window layer may be formed of CdS or CdZnS, as examples. The optional window layer 122 can have a thickness ranging from about 0.01 μm to about 0.1 μm. The p/n junction is formed between the optional window layer 122 and the absorber layer 107.

In FIGS. 4 and 4A, the semiconductor absorber layer 107 can have a thickness ranging from about 0.1 μm to about 1 μm, or from about 0.001 to about 0.1 μm. The semiconductor absorber layer 106 can have a thickness ranging from about 1 μm to about 10 μm. CdTe and CdSₓTe₁₋ₓ layers 106, 107 are multi-crystalline (i.e., there are a plurality of grains 118) and have large sized grains 118. The semiconductor absorber layer 106 can have an average grain size from about 4 μm to about 14 μm, from about 8 μm to about 14 μm, or from about 5 μm to about 8 μm. The semiconductor absorber layers 106 and 107 can each have a ratio of average grain size to thickness (d/t) from about 2 to about 50, from about 4 to about 20, or from about 2.5 to about 10. It is noted that the average grain size may be larger than the deposited absorber layer thickness, due to recrystallization during heat annealing, described further below.

The concentration of sulfur may be uniform within the grains 118′. However, the sulfur may be present in higher concentrations at the grain boundaries 117′, the interface 120 of the absorber layers 106 and 107 and the interface 119 of the semiconductor layer absorber 107 and the TCO stack 110, than within the grains 118′. Alternatively, the sulfur concentration of absorber layer 107 can be higher adjacent to the TCO stack 110, within the grains 118′ and/or at the grain boundaries 117′, and decrease as the distance from the TCO stack 110 increases. The average sulfur concentration of the absorber layer 107 can be from about 1×10¹⁷ atoms/cm³ to about 1×10²⁰ atoms/cm³, or from about 1×10¹⁷ atoms/cm³ to about 1×10¹⁹ atoms/cm³.

It is believed that the photovoltaic devices 100 of FIGS. 4 and 4A can achieve an efficiency in a range from about 14% to about 20%, to about 21%, or to about 22% and an open current voltage from about 700 mV to about 1000 mV.

It is noted that the grains 118, 118′ and the thickness of their respective absorber layers 106, 107, are shown in the schematic diagrams of FIGS. 2-4A to be coextensive in thickness for simplification purposes only. As described above, various ratios of average grain size to thickness can be achieved.

In each of the embodiments described above in connection with FIGS. 2-4A, the semiconductor absorber layer 107 and/or 106 can be doped with or otherwise contain elements for passivating the grain boundaries and defects within the structure of the materials that may trap charge carriers. For example, semiconductor absorber layer 107 and/or semiconductor absorber layer 106 can be doped or otherwise contain oxygen, nitrogen, chlorine, selenium or other elements. The concentration of one or more of these elements may be uniform within the grains 118, 118′.

Embodiments described herein also provide a method of forming photovoltaic devices 100 shown in FIGS. 2-4A in which the absorber layer 106 and/or the absorber layer107 has the large size grains and grain to thickness ratios discussed above. The method involves forming a semiconductor absorber layer (106 and 107) over a substrate, applying a halide compound over an exposed surface of the semiconductor absorber layer, forming a cover or containment layer over the surface of the semiconductor absorber layer upon which the halide was applied, and heat annealing the semiconductor absorber layer to activate the semiconductor absorber layer.

In accordance with the method provided, the cover or containment layer serves as a barrier between the absorber layer (106 and 107), including any dopant or activator (e.g., halide compound such as cadmium chloride) applied to a surface of the semiconductor absorber layer, and a processing environment (e.g., an oven ambient) to limit vapor communication between the absorber layer and processing environment as it undergoes heat treatment.

Vapor communication between the absorber layer (106 and 107) and a processing environment can lead to sublimation and loss to the processing environment of CdTe, sulfur and/or halide; chlorine gas loss to the processing environment; and exposure of the absorber layer (106 and 107) to water vapor or other contaminants. Open vapor communication with the oven environment reduces the effect of the halide compound in activating the absorber layer (106 and 107) due to sublimation and loss of the halide and thus slows absorber layer grain growth. The cover or containment layer therefore makes the halide compound treatment less sensitive to vapor flow in the oven ambient to more effectively increase average grain size within the absorber layer (106 and 107).

In addition, the cover or containment layer allows the absorber layer (106 and/or 107) to be annealed at higher than typical annealing temperatures (e.g., above 440° C. or between about 440° C. and about 800° C.) and/or for longer periods of time (e.g., from about 10 min to about 60 min) because the cover or containment layer prevents undesired oxidation of the absorber layer (106 and 107), which is known to occur at such high annealing temperatures because it forms a barrier between the layer and the source of oxygen (i.e., the ambient air in the oven. Higher annealing temperatures and/or longer annealing times support larger grain growth through recrystallization. The cover or containment layer also allows for the use of more volatile halide compounds to activate the absorber layer (106 and 107) and the use of more volatile p-type dopants, if desired, because it prevents the loss of the volatile compounds and dopants to the processing environment.

By using the cover or containment layer, grain (i.e., crystallite) size of the absorber layer (106 and 107) of larger than 2 μm can be achieved. Thus, depending on specification, the absorber layer (106 and 107) may have an average grain size of about 4 μm to about 14 μm, of about 8 μm to about 14 μm, or of about 5 μm to about 8 μm as discussed above. The ratio of average grain size to thickness (d/t) may go from greater than 2 to about 50, from about 4 to about 20, or from about 2.5 to 10 as per specification.

FIGS. 5-15 depict the formation of the devices 100 according to the various embodiments described above.

FIGS. 5-7A depict an unfinished device 5 at an intermediate stage of processing and, in particular, depicts the formation of the semiconductor layer stack 111 according to the embodiments of FIGS. 2-4A.

Specifically, as shown in FIGS. 5 and 5A, a CdTe absorber layer 106 is formed directly on the TCO stack 110 (FIG. 5) to form the FIG. 2 embodiment, or a CdTe absorber layer 106 is formed over a CdS or CdZnS window layer 122 (FIG. 5A), which in turn is formed over TCO stack 110 to form the FIG. 2A embodiment.

As shown in FIGS. 6 and 6A, to form the device 100 according to the FIGS. 3 and 3A embodiments, respectively, a CdSₓTe₁₋ₓ (where 0≦x≦1 and preferably 0.001≦x≦0.03) absorber layer 107 is formed directly over the TCO stack 110 (FIG. 6) or the CdSₓTe₁₋ₓ absorber layer 107 is formed over a CdS or CdZnS window layer 122 (FIG. 6A) which in turn is formed over TCO stack 110 to form the FIG. 3 embodiment. To form the FIG. 3A embodiment, the absorber layer 107 is formed by first depositing an window layer 122 formed of CdS or CdZnS, and then depositing on window layer 122 a CdTe layer with the optional window layer 122 having thicknesses such that it is completely (FIG. 6) or partially (FIG. 6A) consumed because the sulfur diffuses into the CdTe layer to form the CdSₓTe₁₋ₓ absorber layer 107 during the heat treating activation of the absorber layer. It is also possible to directly deposit a CdTe layer with sulfur during its formation to produce the CdSₓTe₁₋ₓ absorber layer 107.

As shown in FIG. 7, to form the device 100 according to FIG. 4, the absorber layer 106 formed of CdTe, for example, is formed over the CdSₓTe₁₋ₓ absorber layer 107. In turn, the CdSₓTe₁₋ₓ absorber layer 107 is formed over TCO stack 110. As shown in FIG. 7A, the device 100 according to FIG. 4A is formed in the same fashion as that of FIG. 4, except a window layer 122 formed of CdS or CdZnS, is formed between absorber layer 107 and TCO stack 110.

In FIGS. 7 and 7A, the semiconductor absorber layer 107 may be formed by depositing the window layer 122 formed of CdS or CdZnS, for example, and the absorber layer 106 formed of CdTe (as shown in FIG. 5A) having thicknesses such that the optional window layer 122 is completely (FIG. 7) or partially (FIG. 7A) consumed because the sulfur diffuses into only a portion of the absorber layer 106, during chloride heat treatment thereby forming the absorber layer 107 made of CdSₓTe₁₋ₓ. In FIGS. 7 and 7A, since the sulfur is not diffused into the absorber layer 106 sufficiently to cause all of the CdTe to become the alloy CdSₓTe₁₋ₓ, the absorber layer 106 remains. It is also possible to directly dope a CdTe layer with sulfur during its formation to produce the CdSₓTe₁₋ₓ absorber layer 107 upon which an undoped CdTe layer is formed to form absorber layer 106.

Following formation of the desired semiconductor layer stack 111 as described above in connection with FIGS. 5-7A, a halide compound is applied to the exposed surface of the semiconductor layer stack 111. FIG. 8 illustrates a schematic diagram of a processing area or zone 201 of an oven 300 used for applying the halide. The oven 300 may be any suitable deposition oven or other known deposition apparatus. Although this and other embodiments are described using a vapor transport deposition process, any other suitable deposition process may be used.

An unfinished photovoltaic device 5, having an absorber layer 106 and/or 107 at the upper portion of semiconductor stack 111, is transported through the zone 201 of the oven 300 on a support structure 210. The support structure 210 can be a moving belt, driver rollers, or other structure capable of conveying the photovoltaic device 5 through the zone 201.

In this embodiment, a halide compound such as cadmium chloride, manganese chloride, magnesium chloride, zinc chloride, ammonium chloride, or any other chloride compound, is applied to the exposed surface of the absorber layer 106 and/or 107 in zone 201. The halide compound can be applied in vapor or liquid form. The oven 300 can include a vaporization unit 220 to vaporize the halide compound prior to application. Although the vaporization unit 220 is shown to be located inside the oven 300 in this embodiment, it may also be located outside of the oven 300.

The halide compound may be provided to the vaporization unit 220 through an input line 250, for example, in solid (e.g., powder) form or in liquid form. If provided in liquid form, the halide compound may have any suitable concentration. For example, if cadmium chloride is employed, cadmium chloride may be provided as an aqueous solution with a cadmium chloride concentration of about 100-300 g/L. Other suitable halide compounds and concentrations are described in U.S. Provisional Patent Application Ser. No. 61/649,403, entitled “Method of Providing Chloride Treatment for a Photovoltaic Device and a Chloride Treated Photovoltaic Device,” filed on May 21, 2012, the disclosure of which is herein incorporated by reference.

A carrier gas may optionally be supplied to the vaporization unit 220 through an optional carrier gas input line 240 to distribute the vaporized halide compound. The carrier gas used can be an inert gas such as hydrogen, helium, nitrogen, neon, argon, krypton, or a mixture thereof. Alternatively, the carrier gas may be omitted and the halide compound vapor may diffuse under ambient conditions.

In this embodiment, the halide compound is introduced into the oven 300 ambient through a diffuser 260 and deposited onto the moving photovoltaic device 5 in an amount and at an appropriate location to deposit a desired amount of halide compound onto the device 5 in a continuous process, for example. The photovoltaic device 5 is continuously transported through the oven 300 by support structure 210. If the halide compound is deposited in liquid form, the vaporization unit 220 may be omitted and the input line 250 would supply liquid halide compound directly to one or more sprayers which would replace diffuser 260.

In this embodiment, the halide compound is deposited onto a surface of the absorber layer 106 and/or 107 in zone 201 of the oven 300. However, the halide compound can also be applied prior to entering the oven 300. After application of the halide compound a containment layer or a cover is formed or deposited over the absorber layer 106 and/or 107. Embodiments for forming a containment layer are described in connection with FIGS. 9-10. Embodiments for employing a cover are described in connection with FIGS. 11-13B.

FIG. 9 depicts the device 5 with a containment layer 811 formed on the semiconductor layer stack 111. The containment layer 811 can be an inorganic compound that is liquid at high annealing temperatures of between about 440° C. and about 800° C., or above 440° C., so that the contaminant layer such as boron trioxide (B₂O₃) or boric acid (H₃BO₃), among other compounds, or a combination thereof.

FIG. 10 illustrates a schematic diagram of a zone 202 of the oven 300 used for foaming a containment layer 811 over an exposed surface of the semiconductor layer stack 111, after a halide compound is applied. In this embodiment, the containment layer 811 can be deposited as a liquid solution. However, in another embodiment, the containment layer can be deposited as a slurry using known screen printing techniques.

Input line 251 provides a solution of a material boron trioxide or boric acid, for example, at any suitable concentration to a sprayer 270. An optional second input line 252 may also supply the solution of boron trioxide or boric acid to the sprayer 270. In this embodiment, the boron trioxide or boric acid is introduced into zone 202 of the oven 300 ambient through the sprayer 270 and deposited onto the moving photovoltaic device 5 to deposit the containment layer 811 onto the semiconductor stack 111 of the device 5 in a continuous process, for example. However, the containment layer 811 may be deposited in a separate oven or deposition apparatus using any known deposition process. In another embodiment, the containment layer 811 can be co-deposited simultaneously with, or combined with, the halide compound, described above with respect to FIG. 8.

Table 1 below lists a plurality of materials that may be used to form the containment layer 811. Although the materials used to form the containment layer need not possess all of the following properties, an ideal containment layer material should: (1) melt at relatively low temperature, i.e., below about 450° C. so that it will be a liquid at the applicable processing temperatures and able to for a continuous barrier from the ambient processing environment, (2) wet a semiconductor absorber layer surface to form a continuous glaze thereon to for a continuous barrier from the ambient processing environment, (3) serve as a barrier to oxygen present in the processing environment, (4) allow water loss from hydrates formed on the surface of the semiconductor absorber layer, (5) float on top of the semiconductor absorber layer surface and not diffuse into the absorber layer, (6) not source impurities into the semiconductor absorber layer film, (7) be easily applied either as a solution or as a slurry, (8) be easily removed, for example by rinsing or dissolving in a solvent that will not affect the materials of the stack 111, and (9) have a low vapor pressure such that it will not escape into the ambient environment in the oven.

TABLE 1
Exemplary Containment Layer Materials

| | | | Solubility | |
|---|---|---|---|---|
| | Melting | | in H₂O | |
| | Point | Transition/Boiling | @ 25° C. | Density |
| Material | (° C.) | Point (° C.) | (g/l) | (g/cm³) |
| Boric Acid | 171 | 170 | 57 | 1.44 |
| (H₃BO₃) | | H₃BO₃→HBO₂ + H₂O | (pH~4) | |
| Metaboric Acid | 236 | 300 | | |
| (HBO₂) | | HBO₂→B₂O₃ + H₂O | | |
| Boron Trioxide | 450-510 | 1500 | 22 | 2.46 |
| (B₂O₃) | | (sublimates) | | |
| Borax | 743 | 1575 | 25 | |
| (Na₂B₄O₇*10H₂O) | | (boiling point) | | |
| or | | | | |
| Sodium Borate | | | | |
| Vanadium Oxide | 690 | 1550 | 0.8 | |
| (V₂O₅) | | | | |
| Sodium Nitrate | 308 | 380 | 921 | 2.26 |
| (NaNO₃) | | (decomposes) | | |

Classes of containment layer materials can include halides, borates, oxides, nitrates, sulfates, carbonates and phosphates. Other containment layer materials can include NaAlCl₄ and nitrate mixtures such as a K—Na—Ca nitrate mixture or a K—Na—Li nitrate mixture, for example, KNO₃, NaNO₃ and Ca(NO₃)₂ mixtures. As shown in the properties of NaNO₃ listed in Table 1, the nitrate mixtures meet the criteria of relatively low melting points and high water solubility. The nitrate mixtures can be used as heat transfer mixtures that are not highly corrosive. In addition, water-soluble silicates such as sodium silicate (Na₂O—SiO₂) and potassium silicate (K₂O—SiO₂) may also be used as containment layer 811 materials.

Referring to FIG. 10, the oven 300 may also include a plurality of heaters 230 to maintain an appropriate temperature within zone 202 of the oven 300. During containment layer 811 formation, depending on the containment layer material used, the temperature of zone 202 must be maintained at a temperature equal to or above the melting point of the containment layer material, to ensure that the containment layer material is deposited and remains in liquid form. In another embodiment, containment layer 811 formation may occur simultaneously with annealing process (FIG. 14) to ensure that such a required temperature is maintained.

FIGS. 11, 12 and 13A depict the device 5 with a cover 1011, 1012, 1013 according to various embodiments, arranged over the semiconductor layer stack 111.

As shown in FIG. 11, the cover 1011 includes a layer of sulfur-containing material 301 and a supporting substrate 302. The sulfur-containing material 301 may be a layer of CdS or other sulfur-containing materials can be used. The substrate 302 can be any suitable material that will provide an enclosed environment over the semiconductor layer stack 111 during the annealing process (FIG. 14) to prevent the loss of halide and, if present, sulfur or other dopants from the enclosed environment during the annealing process. The substrate 302 may be formed of glass, or may be a multilayered structure including glass and having an optional CdTe layer 303 between the glass and the sulfur containing material 301. The sulfur-containing material 301 is oriented to face and be adjacent to the semiconductor layer stack 111. The cover 1011 and the semiconductor layer stack 111 can be spaced apart by a distance 305. The distance 305 can be from about 0 mm (such that the sulfur-containing material 301 is in contact with the semiconductor layer stack 111) to about 20 mm.

Referring to FIG. 12, in this embodiment a cover 1012 may be any suitable material, such as CdS, cadmium telluride (CdTe), zinc telluride (ZnTe), a dielectric material (such as glass), or other material, capable of containing the out diffusion of halide and, if present, sulfur from the enclosed environment during the annealing process (FIG. 14). The cover 1012 and the semiconductor layer stack 111 can be spaced apart by a distance 405. The cover 1012 can be spaced from the semiconductor layer stack 111 by any method or apparatus known in the art. The distance 405 can be from about 0.5 mm to about 20 mm such that the cover 1012 is not in contact with the semiconductor layer stack 111.

Referring to FIGS. 13A-13B, according to a further embodiment, a cover 1013 can be configured as a close-space oven anneal tunnel through which the device 5 passes. In the illustrated embodiment, an upper wall 502 defining a zone 203 of oven 300 serves as the cover 1013. FIG. 13A is a cross sectional view of the zone 203 of oven 300 along the line 13A-13A′ of FIG. 13B. The walls 502 of zone 203 can be any suitable material, such as glass, ceramic or metal and can optionally be coated with a sulfur-containing material, such as CdS. Optionally input lines (or openings) 253 and 254 are included to permit the injection or flow of gas into the space between the surface of the semiconductor layer stack 111 and the cover 1013 (or cover 1011, 1012 with respect to the embodiments of FIGS. 11 and 12, in which case the input lines would be located in the oven 300, similar to input lines 251 and 252 shown in FIG. 10). Additionally, the zone 203 can include a plurality of heaters 230 to maintain an appropriate temperature for an annealing process (described below in connection with FIG. 14).

Once the containment layer 811 or cover 1011, 1012 is in place (or in the case of the FIG. 13A-13B embodiment, once the device 5 is transported to be within the cover 1013), a heating/annealing process is conducted.

FIG. 14 illustrates a schematic of a zone 204 of the oven 300 used for the annealing process. The oven 300 can include a plurality of heaters 230 to maintain an appropriate temperature for CdTe and/or CdSₓTe₁₋ₓ annealing. The anneal is conducted at one or more temperatures from about 440° C. to about 800° C., for a period of time from about 10 min to about 60 min or longer. In one embodiment, the anneal is conducted in an environment inside the oven 300 comprising one or a mixture of ambient air, nitrogen (N₂), oxygen (O₂) and argon (Ar) introduced through a diffuser 271 or other deposition device. Alternatively, the annealing process may be conducted within zone 203 as depicted in FIGS. 13A-13B.

Typically, without the containment layer 811 or cover 1011, 1012, 1013, a semiconductor absorber layer would be annealed at between about 400° C. and about 440° C. for less than about 30 minutes because, at higher temperatures and/or longer processing times, deposited halide compound, sulfur and CdTe can escape into the ambient of the oven 300, and excessive oxidation and exposure to water vapor of the CdTe and/or CdSₓTe₁₋ₓ film can occur. The containment layer 811 or cover 1011, 1012, 1013 serves as a barrier between the absorber layer 106 and/or 107 being annealed and the oven 300 ambient to prevent such vapor communication/escape.

In addition, the vapor communication barrier created by the containment layer 811 and cover 1011, 1012, 1013 also allows for the use of more volatile chloride compounds such as zinc chloride and ammonium chloride in lieu of cadmium chloride. The containment layer 811 or cover 1011, 1012, 1013 also permits the use of more volatile p-type dopants and reactants to dope the CdTe and/or CdSₓTe₁₋ₓ prior to the heat anneal, such as phosphorous (P), phosphorous tri-chloride (PCl₃), phosphorous pentoxide (P₂O₅), and antimony tri-chloride (SbCl₃) or other suitable dopants, which are too volatile for use with an uncontained CdTe and/or CdSₓTe₁₋ₓ film. The p-type dopant may be incorporated into the semiconductor layer stack 111 before, during or after deposition of the absorber layers 106 and/or 107 using any known doping technique. For example, the dopant can be supplied from an incoming dopant powder to be combined with a material to be deposited such as CdTe and/or CdSₓTe₁₋ₓ, a carrier gas, or a directly doped powder such as a CdTe and/or CdSₓTe₁₋ₓ-Phosphorous powder. Alternatively, the dopant can be supplied by diffusion from another layer of the photovoltaic device 100. For example, a dopant within one layer can diffuse into the layer(s) of the semiconductor layer stack 111. Any suitable dopant quantity and concentration may be used, as desired.

In FIGS. 5A, 6, 6A, 7 and 7A where sulfur is present in the semiconductor layer stack 111, the containment layer 811 or cover 1011, 1012, 1013 also allows some sulfur diffusion within layers of the semiconductor layer stack 111. For example, where the structure of FIG. 5A is annealed as described above, sulfur from the optional window layer 122 can diffuse into the absorber layer 106 during the anneal to form a sulfur profile as CdSₓTe₁₋ₓ at the interface of the CdTe absorber layer 106, but prevents excessive sulfur diffusion out of device 5 and into the ambient atmosphere. In a typical photovoltaic device including a CdTe absorber layer and a CdS window layer, an anneal at higher temperatures and/or longer time without a containment layer 811 or cover 1011, 1012, 1013, excessive sulfur diffusion out of device might cause a discontinuous p/n junction between the CdTe absorber layer and CdS window layer, which would impair the function of the device.

Where the cover 1011, 1012, 1013 includes sulfur and is spaced apart from the surface of the semiconductor layer stack 111, the sulfur can evaporate to serve as a sulfur source for diffusion into the layers of the semiconductor layer stack 111. Where the cover 1011, 1012, 1013 includes sulfur and is in contact with the absorber layer, the sulfur can diffuse directly into the semiconductor layer stack 111 surface. In the case where the device 100 will include an optional window layer 122 (FIGS. 2A, 3A and 4A), sulfur provided with the cover 1011, 1012, 1013 can limit sulfur diffusion into the absorber layer 106 from the optional window layer 122 to ensure that there is a continuous window layer 122 in the final device 100.

Further, in embodiments of FIGS. 5A, 6, 6A, 7 and 7A, the containment layer 811 or cover 1011, 1012, 1013 creates an anneal environment that results in a greater concentration of sulfur, including at grain boundaries 118 (FIGS. 2A, 3, 3A, 4 and 4A), than would be achieved without the containment layer 811 or cover 1011, 1012, 1013. This increased level of sulfur, with the presence of the halide, promotes re-crystallization of the absorber layers 106 and/or 107.

FIG. 15 illustrates a schematic diagram of a zone 205 of the oven 300 used for removing the containment layer that has been formed directly on the surface of semiconductor layer stack 111 (and residue of the halide compound, if any) after the semiconductor absorber layer 106 and/or 107 is annealed. Input line 255 provides a removal agent, for example, sulfuric acid, ethanol or other suitable acid or material, at any suitable concentration to a sprayer 272. An optional second input line 256 may also supply the removal agent to the sprayer 272. In this embodiment, the removal agent is introduced through the sprayer 272 and deposited onto the moving photovoltaic device 5 in an amount and at an appropriate location so as to dissolve, rinse off, or otherwise remove the containment layer 811 from the photovoltaic device 5 in a continuous process, for example. However, in other embodiments, similar removal techniques may be employed outside of the oven 300 in a separate apparatus, as desired.

Where the cover 1011, 1012, 1013 is present, it is physically or mechanically removed (rather than needing chemical removal). For example, the cover 1011, 1012 is physically removed from the device 100 or the device 100 is transported away from the cover 1013.

Although the above-described embodiments indicate that halide compound application (FIG. 8), use of a containment layer 811 or cover 1011, 1012, 1013 (FIGS. 9-13B), semiconductor absorber layer annealing (FIG. 14), occur in different zones of an oven 300, such steps can occur in one or more successive zones or in one or more different ovens. In addition, one or more of such steps, for example, formation of containment layer 811 or cover 1011, 1012 (FIGS. 9-13B), may occur outside of an oven in a separate apparatus.

After the containment layer 811 or cover 1011, 1012 is removed (or the device is transported away from cover 1013), the optional ZnTe layer can be deposited over the annealed absorber layer 106 and/or 107 before the back contact 108 is deposited, which serves as an electrical contact for the photovoltaic device 100. The back support 109 may then be formed above the back contact 108 to achieve the structure of FIG. 1.

Details of one or more embodiments are set forth in the accompanying drawings and description. Other features, objects, and advantages will be apparent from the description, drawings, and claims. Although a number of embodiments have been described, it will be understood that various modifications may be made without departing from the spirit and scope of the invention. It should also be understood that the appended drawings are not necessarily to scale, presenting a somewhat simplified representation of various features and basic principles of the invention.

What is claimed as new and desired to be protected by Letters Patent of the United States is:

1. A photovoltaic device comprising:
at least one semiconductor layer having an average grain size to thickness ratio from greater than 2 to about 50.

2. The device of claim 1, wherein the average grain size to thickness ratio is from about 4 to about 20.

3. The device of claim 1, wherein the average grain size to thickness ratio is from about 2.5 to about 10.

4. The device of claim 1, wherein the at least one semiconductor layer comprises an absorber layer.

5. The device of claim 4, wherein the absorber layer comprises CdTe.

6. The device of claim 4, wherein the absorber layer comprises CdSₓTe₁₋ₓ, and wherein 0<x<1.

7. The device of claim 4, wherein the absorber layer is a bi-layer comprising a CdSₓTe₁₋ₓ layer and a CdTe layer, and wherein 0<x<1.

8. The device of claim 6, wherein 0.001≦x≦0.03.

9. The device of claim 6, wherein an average sulfur concentration of the absorber layer is from about 1×10¹⁷ atoms/cm³ to about 1×10²⁰ atoms/cm³.

10. The device of claim 6, wherein the absorber layer has a plurality of grains, and wherein sulfur is present within the absorber layer in higher concentrations at grain boundaries than within the plurality of grains.

11. The device of claim 10, further comprising a transparent conductive oxide stack in contact with the absorber layer, wherein sulfur is present in higher concentrations at an interface between the transparent conductive oxide stack and the absorber layer than within the plurality of grains.

12. The device of claim 6, further comprising a zinc telluride layer in contact with the absorber layer.

13. A photovoltaic device comprising:
at least one semiconductor layer having an average grain size of between about 4 μm and about 14 μm.

14. The device of claim 13, wherein the average grain size is between about 5 μm and about 8 μm.

15. The device of claim 13, wherein the average grain size is between about 8 μm and about 14 μm

16. The device of claim 13, wherein the at least one semiconductor layer comprises an absorber layer.

17. The device of claim 16, wherein the absorber layer comprises CdTe.

18. The device of claim 16, wherein the absorber layer comprises CdSₓTe₁₋ₓ, and wherein 0<x<1

19. The device of claim 16, wherein the absorber layer is a bi-layer comprising a CdSₓTe₁₋ₓ layer and a CdTe layer, and wherein 0<x<1.

20. The device of claim 18, wherein the absorber layer comprises a plurality of grains, and wherein the absorber layer has an average grain size to thickness ratio from greater than 2 to about 50.

21. The device of claim 18, wherein 0.001≦x≦0.03.

22. The device of claim 18, further comprising a transparent conductive oxide stack in contact with the absorber layer, wherein sulfur is present within the absorber layer in higher concentrations at grain boundaries and at an interface of the absorber layer and the transparent conductive oxide stack than within the grains.

23. The device of claim 18, wherein an average sulfur concentration within the absorber layer is from about 1×10¹⁷ atoms/cm³ to about 1×10²⁰ atoms/cm³.

24. A method of forming a photovoltaic device, comprising:
forming a semiconductor absorber layer over a first substrate;
applying a halide compound over at least one surface of the absorber layer;
providing one of a containment layer and cover over the absorber layer; and
annealing the semiconductor layer by heating it for a period of time while the containment layer or cover is over the absorber layer.

25. A method as in claim 24, wherein the cover comprises a second substrate having a planar surface which faces the absorber layer.

26. A method as in claim 25, wherein the cover comprises sulfur-containing material on the second substrate, the sulfur-containing material facing the absorber layer.

27. A method as in claim 26, wherein the anneal causes sulfur from the sulfur-containing material to be incorporated into the absorber layer.

28. A method as in claim 26, wherein the sulfur-containing material comprises CdS.

29. A method as in claim 26, wherein the sulfur-containing material is in contact with the absorber layer.

30. A method as in claim 26, wherein the sulfur-containing layer is spaced from the absorber layer by a by a distance less than or equal to about 20 mm.

31. A method as in claim 26, further comprising flowing a gas into the space between the sulfur-containing layer and the absorber layer.

32. A method as in claim 31, wherein the gas is a member selected from the group consisting of air, nitrogen, argon, oxygen and a mixture thereof.

33. A method as in claim 24, wherein the cover comprises a material which is a member of the group consisting of CdS, cadmium telluride, zinc telluride, metal and a dielectric material.

34. A method as in claim 24, wherein the cover is in contact with the absorber layer.

35. A method as in claim 24, wherein the cover is spaced from the absorber layer by a distance less than or equal to about 20 mm.

36. A method as in claim 35, further comprising flowing a gas in the space between the cover and the absorber layer.

37. A method as in claim 36, wherein the gas is a member selected from the group consisting of air, nitrogen, argon, oxygen and a mixture thereof.

38. A method as in claim 24, wherein the cover is configured as a close-space anneal tunnel through which the device passes.

39. A method as in claim 38, wherein the cover has a coating of a sulfur containing material which faces the absorber layer.

40. A method as in claim 38, wherein the cover includes a plurality of openings, and further comprising flowing a gas through the at least one of the openings into a space between a surface of the cover and the absorber layer.

41. A method as in claim 40, wherein the gas is selected from the group consisting of air, nitrogen, argon, oxygen and a mixture thereof.

42. A method as in claim 24, further comprising, prior to the annealing, forming a CdS window layer beneath and in contact with the absorber layer.

43. A method as in claim 42, wherein the absorber layer comprises CdTe, and wherein the annealing causes all or a portion of the CdS window layer to be incorporated into the absorber layer to form a layer of CdSₓTe₁₋ₓ, where 0<x<1.

44. A method as in claim 43, wherein the annealing causes a portion of the CdS window layer to be incorporated into the absorber layer to form a layer of CdSₓTe₁₋ₓ between the CdS layer and the absorber layer.

45. A method as in claim 43, wherein the annealing causes all of the CdS window layer to be incorporated into the absorber layer to form a layer of CdSₓTe₁₋ₓ in contact with the absorber layer.

46. A method as in claim 43, wherein the annealing causes all of the CdS layer to be incorporated throughout the absorber layer to form a layer of CdSₓTe₁₋ₓ in place of the CdS layer and the absorber layer.

47. The method of claim 24, wherein the containment layer includes a material selected from the group consisting of halides, borates, oxides, nitrates, sulfates, carbonates, phosphates, NaAlCl₄, nitrate mixtures and silicates.

48. The method of claim 47, wherein the containment layer includes a material selected from the group consisting of boron trioxide, boric acid, metaboric acid, borax, vanadium oxide and sodium nitrate.

49. The method of claim 48, wherein the containment layer includes a material selected from the group consisting of boron trioxide and boric acid.

50. The method of claim 24, wherein the containment layer is formed and the halide compound is applied simultaneously.

51. The method of claim 24, wherein the halide compound is a chloride compound.

52. The method of claim 24, further comprising, before the annealing, doping the absorber layer with a dopant selected from the group consisting of phosphorous, phosphorous tri-chloride, phosphorous pentoxide and antimony tri-chloride.

53. The method of claim 24, wherein the absorber layer comprises CdTe.

54. The method of claim 24, further comprising removing the containment layer or cover after the annealing.

55. A method as in claim 24, wherein the containment layer or cover reduces out diffusion of at least one of the halide and sulfur from the device during the annealing.

56. A method as in claim 24, wherein the anneal is conducted at a temperature in the range of about 440° C. to about 800° C.

57. A method as in claim 24, wherein the anneal is conducted at a temperature above 440° C.

58. The method of claim 24, wherein the anneal is conducted from about 10 min to about 60 min.

59. A method as in claim 24, wherein the anneal is conducted at a temperature in the range of about 440° C. to about 800° C. for a period of between about 10 min and about 60 min.

60. A method of processing a CdTe layer of a photovoltaic device, the method comprising:
applying a halide compound over at least one surface of the CdTe layer;
forming one of a containment layer or cover over at least one surface of the CdTe layer, the containment layer or cover providing a vapor barrier between the at least one surface of the semiconductor absorber layer and an ambient environment above the cover; and
subsequent to forming the containment layer or cover, annealing the CdTe layer by heating for a period of time.

61. The method of claim 60, wherein the containment layer includes a material selected from the group consisting of halides, borates, oxides, nitrates, sulfates, carbonates, phosphates, molten salt batteries, heat storage systems and silicates.

62. The method of claim 61, wherein the containment layer includes a material selected from the group consisting of boron trioxide, boric acid, metaboric acid, borax, vanadium oxide and sodium nitrate.

63. The method of claim 60, wherein containment layer formation and halide compound application occur simultaneously.

64. The method of claim 60, wherein the halide compound is a chloride compound selected from the group consisting of cadmium chloride, ammonium chloride, and zinc chloride.

65. The method of claim 60, further comprising doping the CdTe layer with a dopant selected from the group consisting of phosphorous, phosphorous tri-chloride, phosphorous pentoxide and antimony tri-chloride, prior to annealing the CdTe layer.

66. The method of claim 60, wherein the CdTe layer is annealed at between about 440° C. and about 800° C.

67. A method of claim 60, wherein the CdTe layer is annealed at a temperature above 440° C.

68. The method of claim 60, wherein the CdTe layer is annealed from about 10 min to about 60 min.

69. A method of claim 60, wherein the CdTe layer annealed at between about 440° C. and about 800° C. for a period of between about 10 min and about 60 min.
